(19) United States
(12) Patent Application Publication
(10) Pub. No.: US 2025/0261413 A1
(43) Pub. Date: Aug. 14, 2025

(54) TRENCH TERMINATION STRUCTURE AND METHOD OF MAKING THEREOF

(71) Applicant: Alpha and Omega Semiconductor International LP, Toronto (CA)

(72) Inventors: Zhibo Guo, San Jose, CA (US); Karthik Padmanabhan, Palo Alto, CA (US); Lingpeng Guan, San Jose, CA (US); Changqing Zhan, Vancouver, WA (US); Madhur Bobde, Sunnyvale, CA (US)

(21) Appl. No.: 18/440,125

(22) Filed: Feb. 13, 2024

(51) Int. Cl. H01L 29/06; H01L 21/768

(52) U.S. Cl. CPC H10D 62/102; H01L 21/76816; H10D 62/104

(57) ABSTRACT

A semiconductor device and method for making the structure thereof are disclosed. The device includes a semiconductor substrate composition having an active region, a transition region and a first termination region. An active trench gate structure is disposed in the active region and a first termination trench structure is disposed in the first termination region and laterally separated from the active trench by the transition region having a transition trench structure. The first termination trench sidewall insulation layer of the first termination trench structure has a similar thickness as a transition trench sidewall insulation layer of the transition trench structure and a gate sidewall insulation layer of the active trench gate structure.

### FIELD OF THE DISCLOSURE

Aspects of the present disclosure relate to transistor devices. More specifically, aspects of the present disclosure relate to a transistor device having an improve termination trench structure.

### BACKGROUND OF THE DISCLOSURE

Trench transistor layouts often include termination trench structures to shape the distribution of electric field at the edge of the active area. These termination structures may increase the breakdown voltage and improve reliability of the device with optimized distribution of electric field and better tolerance of external positive or negative charges.

FIG. 1 is a side cut away view of a prior art semiconductor device with prior art termination region structures. This prior art implementation includes an active region 105, transition region 106, and termination region 107. The active region includes gate trench structures having a gate electrode 111 insulated from the substrate 101 by a thin portion of an insulation layer 113 disposed overtop a shield electrode 114 insulated by a thicker portion of the insulation layer 113 in the gate trench 112. Additionally, the active region includes an active contact 115 which is conductively coupled to a source region and body short in the semiconductor substrate 101 and connected to the source metal 117 of the device. The transition region 106 includes a transition trench structure and transition contact 116. The transition contact 116 is connected to the source metal 117 and conductively coupled to the body region of the device. The transition trench structure includes a transition electrode 110 connected to the source metal 117 and insulated from the substrate 101 by a transition trench 108 insulation layer 109 that is thicker than gate insulation layer 113. Similarly, the termination region 107 includes a termination trench structure with termination electrode 104 in a termination trench 102 insulated from the substrate 101 by an insulation layer 103 thicker than the gate insulation layer.

This prior art termination and transition region design has many issues, first it is costly to produce as production requires multiple insulation layer deposition steps to create the thick insulation layer for the termination region and thin insulation for the gate electrode. This further bars use of this prior art layout in devices formed with a single electrode in each trench as production requires cost prohibitive steps to create the thick insulation in the termination region. It is within this context that aspects of the present disclosure arise.

### BRIEF DESCRIPTION OF THE DRAWINGS

The teachings of the present disclosure can be readily understood by considering the following detailed description in conjunction with the accompanying drawings, in which:

FIG. 1 is a side cut away view of a prior art semiconductor device with prior art termination region structures.

FIG. 2 depicts a cut away side view of a semiconductor device having the improved termination structures according to aspects of the present disclosure.

FIG. 3 depicts a side cut away view of an implementation of a semiconductor device having the improved termination regions with a blanket body implant in the third type of termination region according to aspects of the present disclosure.

FIG. 4 shows a side cut away view of an implementation of a semiconductor device having improved termination regions of the first and third type according to aspects of the present disclosure.

FIG. 5 depicts a side cut away view of an implementation of a semiconductor device having improved termination regions with a first type and third type termination region having a blanket implant body region according to aspects of the present disclosure.

FIG. 6 shows a side cut away view of an implementation of a semiconductor device having improved termination regions with a first type termination region and a second type termination region according to aspects of the present disclosure.

FIG. 7 depicts a side cut away view of an implementation of a semiconductor device having improved termination regions with a first type termination region according to an aspect of the present disclosure.

FIG. 8A is a cut away three-dimensional view showing a width of a substrate composition having a longitudinally continuous BGR located at the bottom of a termination trench structure according to aspects of the present disclosure.

FIG. 8B is a cut away three-dimensional view showing a width of a substrate composition having an longitudinally discontinuous BGR located at the bottom of a termination trench structure according to aspects of the present disclosure.

FIG. 9 is a diagram depicting a top-down view of the device including improved termination regions according to aspects of the present disclosure.

FIG. 10A is a cut away side view of the semiconductor device showing an implementation of a body connection to the termination trench electrode on a side near the active region with a blanket body implant according to an aspect of the present disclosure.

FIG. 10B is a cut away side view of the semiconductor device showing an implementation of a body connection to the termination trench electrode on a side near the active region with doped body region pillars according to an aspect of the present disclosure.

FIG. 10C is a cut away side view of the semiconductor device showing an implementation of a body connection to the termination trench electrode on a side distal from the active region with blanket body implant according to an aspect of the present disclosure.

FIG. 10D is a cut away side view of the semiconductor device showing an implementation of a body connection to the termination trench electrode on a side distal from the active region with pillars of body region according to an aspect of the present disclosure.

FIG. 11 is a graph showing a simulated electric field distribution of an implementation of the semiconductor device with improved termination trench structures according to aspects of the present disclosure.

FIG. 12A through FIG. 12J are side cross-sectional views depicting the formation of the semiconductor device having improved termination regions according to aspects of the present disclosure.

### DESCRIPTION OF THE SPECIFIC EMBODIMENTS

Although the following detailed description contains many specific details for the purposes of illustration, anyone of ordinary skill in the art will appreciate that many variations and alterations to the following details are within the scope of the invention. Accordingly, examples of embodiments of the invention described below are set forth without any loss of generality to, and without imposing limitations upon, the claimed disclosure.

In the following Detailed Description, reference is made to the accompanying drawings, which form a part hereof, and in which are shown by way of illustration specific embodiments in which the invention may be practiced. In this regard, directional terminology, such as “top,” “bottom,” “front,” “back,” “leading,” “trailing,” etc., is used with reference to the orientation of the figure(s) being described. Because components of embodiments of the present disclosure can be positioned in a number of different orientations, the directional terminology is used for purposes of illustration and is in no way limiting. It is to be understood that other embodiments may be utilized, and structural or logical changes may be made without departing from the scope of the present invention. The following detailed description, therefore, is not to be taken in a limiting sense, and the scope of the present invention is defined by the appended claims.

The disclosure herein refers to a semiconductor material, such as silicon, doped with ions of a first conductivity type or a second conductivity type. The ions of the first conductivity type may be opposite ions of the second conductivity type. For example, and without limitation, in some implementations, ions of the first conductivity type may be n-type, which contribute negative charge carriers, e.g., electrons, when doped into silicon. In such implementations, ions of the first conductivity type may include phosphorus, antimony, bismuth, lithium, and arsenic. In such implementations, ions of the second conductivity may be p-type, which create holes for charge carriers when doped into silicon and in this way are referred to as being the opposite of n-type. P-type type ions include boron, aluminum, gallium, and indium. While the above description referred to n-type as the first conductivity type and p-type as the second conductivity type the disclosure is not so limited, p-type may be the first conductivity type and n-type may be the second conductivity type. Furthermore, semiconductor materials other than silicon may be used in MOSFET devices in accordance with aspects of the present disclosure.

In the following Detailed Description, reference is made to the accompanying drawings, which form a part hereof, and in which are shown by way of illustration of specific embodiments in which the invention may be practiced. For convenience, use of + or − after a designation of conductivity or net impurity carrier type (p or n) refers generally to a relative degree of concentration of a designated type of net impurity carriers within a semiconductor material. In general, terms, an n+ material has a higher n type net dopant (e.g., electron) concentration than an n material, and an n material has a higher carrier concentration than an n-material. Similarly, a p+ material has a higher p type net dopant (e.g., hole) concentration than a p material, and a p material has a higher concentration than a p-material. It is noted that what is relevant is the net concentration of the carriers, not necessarily dopant concentration. For example, a material may be heavily doped with n-type dopants but still have a relatively low net carrier concentration if the material is also sufficiently counter-doped with p-type dopants. As used herein, a concentration of dopants less than about 3e¹⁴ cm⁻³ may be regarded as “lightly doped” and a concentration of dopants greater than about 1e¹⁵ cm⁻³ may be regarded as “heavily doped”.

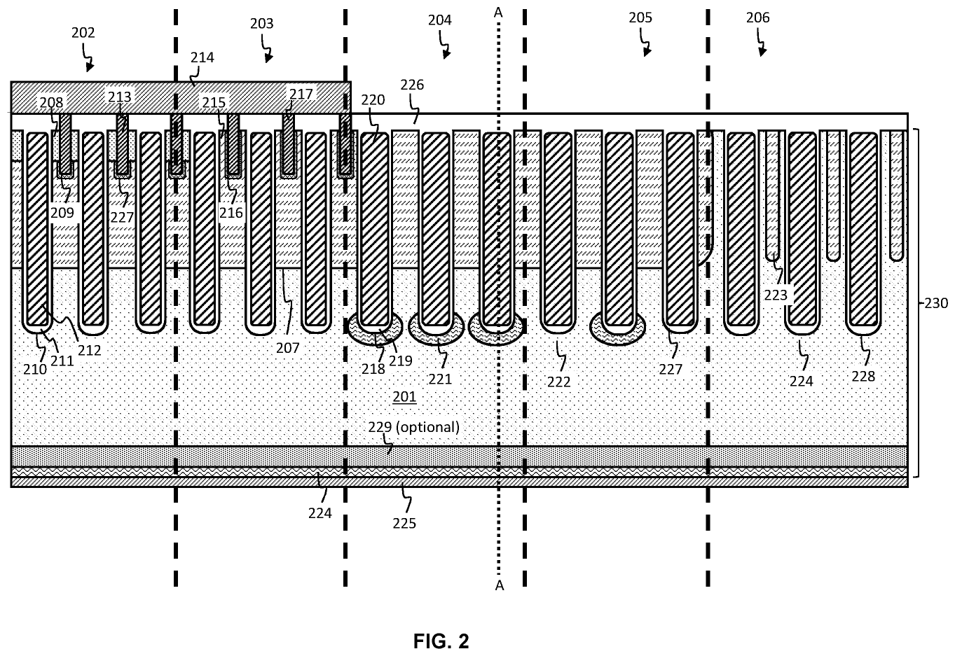

Aspects of the present disclosure improve upon prior layouts for termination regions as they allow more efficient creation of termination regions in single gate polycrystalline electrode transistors. The effect of the improvement is the creation of termination structures that have a trench insulation layer that is similar in thickness to the gate trench insulation layers in the active region. FIG. 2 depicts a cut away side view of a semiconductor device having the improved termination structures according to aspects of the present disclosure. As shown a semiconductor substrate composition 230 includes a semiconductor substrate 201 doped with ions of the first conductivity type. The doping concentration of the semiconductor substrate 201 may be between 1e¹³ and 5e¹⁵ cm⁻². In this implementation the semiconductor substrate composition 230 is divided into five regions. Those regions being an active region 202, a transition region 203, a first termination region 204, a second termination region 205, and a third termination region 206. Together the transition and termination regions are configured to move transient charge away from the active regions thus improving the breakdown resistance of the device.

The active region 202 includes both active contact trenches 209 and gate trenches 210. The gate trenches 210 are formed in the semiconductor substrate 201 and are lined with an insulation layer 211. The insulation layer 211 may be any suitable insulating material for example and without limitation silicon nitride, silicon, etc. A gate electrode 212 is formed on the insulation layer 211 in each gate trench 209. The gate electrode 212 may be made from any suitable conductive material for example and without limitation n-doped polycrystalline silicon (referred to hereinafter as poly or polycrystalline silicon). The top portion of the insulation layer 226 may further be formed over the gate electrodes 212 encapsulating the gate electrodes and insulating in from the substrate composition 230 and a source contact layer 214. A gate electrode contact (not shown) may connect each of the gate electrodes in the active region. In some implementations (not shown) the gate trench may include a shield electrode made from a conductive material formed vertically underneath the gate electrode and insulated from the gate electrode by a portion of the gate insulation layer between the shield electrode and gate electrode.

Active contact trenches 209 are formed in the substrate composition 230. The active contact trenches 209 are filled with a conductive material for example and without limitation tungsten or titanium forming the active contact plug 213. In some implementations, the contact trenches 209 may be lined with a barrier metal, such as titanium nitride before filling the remaining portion of the trenches with contact metal, such as titanium. The active contact plug 213 is connected to the source contact layer 214. The source contact layer 214 may be formed over the active contact plug thus creating a conductive connection between the two elements. The source contact layer is also formed over the top portion of the insulation layer 226 in the active region and may be made from any suitable conductive material for example and without limitation, copper, aluminum, nickel, gold, tungsten, silver, lead, iron, polycrystalline silicon, or any combination thereof.

The active region 202 in this implementation further includes a portion of the body region 207 blanket doped into the substrate layer 201. The blanket doped body region 207 is formed with ions of the second conductive type blanket doped into the substrate layer at a concentration of between 5e¹² and 5e¹³ cm⁻² and with an energy of implantation of between 100 and 900 KeV. A source region 208 is doped into an upper portion of the body region 207 in the active region 202. The source region 208 is formed around the active contact trenches and doped with ions of the first conductivity type at a concentration of between 1e¹⁴ and 5e¹⁵ cm⁻² and may be created with a single implant or multiple implants with an energy of implantation of between 30 and 150 KeV. A body contact region 227 may be formed in the body region at the bottom of each active contact trench 209 in the active region 202. The body contact region may form the body short for the device and may be doped with ions of the second conductivity type at a concentration of between 5e¹² and 5e¹⁵ cm⁻² and with an energy of implantation of between 20 and 350 KeV.

The transition region 203 as shown is similar to the active region. The transition region includes a portion of substrate 201 and blanket doped body region 207. The difference between the active region 202 and the transition region 203 is that the transition region lacks a source region around 215 the transition contact plug 217. Additionally, a transition body contact region 216 may be formed near the bottom of the transition contact trench and extend around the trench up to a top surface of the substrate composition 230. Similar to the active region the transition body contact region may be doped with ions of the second conductivity to a concentration of between 5e¹² and 5e¹⁵ cm⁻² and with an energy of implantation of between 20 and 350 KeV.

The first type of termination region, which is the first termination region 204 as shown, includes termination trench structures and lacks contact structures seen in the active region and transition region. The termination trench structures include a first termination trench 218 formed in the substrate composition 230, termination trench insulating layer 219 formed over a surface of the semiconductor substrate composition in each termination trench 218 and first termination electrode 220. The termination trench insulating layer 219 may be made from any suitable insulating material such as silicon nitride or silicon dioxide. The first termination trench insulating layer may be a similar thickness as the gate trench insulating layer and the transition trench insulating layer because the first termination trench insulating layer 219 may be made in the same formation step as the gate trench insulating layer and the transition trench insulating layer. For example and without limitation, the first termination trench insulating layer and other termination trench insulating layers may be the same thickness as the gate trench insulating layer and transition trench insulating layer. The termination electrode 220 may be made from a conductive material for example and without limitation polycrystalline silicon. The first termination electrode 220 may be a floating electrode insulated from the substrate composition by the top portion of the insulating layer 226. Additionally, a buried guard ring (BGR) 221 is formed near the bottom of each of the first termination trenches 218. The BGRs may be doped into the substrate layer 201 with ions of the second conductivity type with a concentration of between 1e¹² and 5e¹³ cm⁻² with an energy of implantation of between 30 and 300 KeV.

The second type of termination region which is the second termination region 205 as shown includes a subset of second termination trenches having a BGR and a subset of second termination trenches without a BGR 221 formed in the substrate layer 210 near the bottom of the termination trench. The BGRs of the second termination region may be doped into the substrate layer 201 with ions of the second conductivity type with a concentration of between 1e¹² and 5e¹³ cm⁻² with an energy of implantation of between 30 and 300 KeV.

Additionally, as shown, the second termination region includes a portion of the body region 207 blanket doped into the substrate.

The third type of termination region, which is the third termination region 206 shown here, includes pillar-like body regions formed in the substrate mesas between the third termination trenches. The regions of substrate between the third termination trenches 228 form mesas in which pillars of body region 223 are formed. The mesas of substrate may be wider than the body region pillars 223 and the body region pillars may be implanted with ions of the second conductivity type at a concentration of between 5e¹² and 5e¹⁵ cm⁻² and with an energy of implantation of between 100 and 900 KeV. As shown the third termination region 207 lacks BGR regions 224 near the bottom of the third termination trenches.

The backside of the substrate composition 230 may include an optional buffer region 229, for punch-through insulated gate bipolar transistor (IGBT) structures. For MOSFET structures and non-punch-through IGBT structures the buffer region 229 may be excluded. The buffer region may be heavily doped with ions of the first conductivity type. The ion concentration of the buffer region may be between 2e¹² and 3e¹³ cm⁻² and doped into the backside of the substrate layer with an energy of implantation of between 150 KeV and 3 MeV. Alternatively, the buffer region 223 may be grown via epitaxial processes for example and without limitation Chemical Vapor Deposition (CVD). The grown buffer region 229 may be 2 to 15 micrometers thick with a resistivity between 0.1 and 2 Ohm-cm. A backside contact layer 224 formed may be formed in the substrate layer 201 or the buffer region 229. The backside contact layer may be formed with ions of the first conductivity type to create a Field Effect Transistor (FET) or may be formed with ions of the second conductivity type for an Insulated-Gate Bipolar Transistor (IGBT). For FET devices the ion concentration in the backside contact layer may be between 1e¹⁴ and 5e¹⁵ cm⁻² and may be formed with an energy of implantation of between 30 and 150 KeV. For IGBT device the backside contact layer may doped with ions of the second conductivity type to a concentration of between 5e¹² and 5e¹⁵ cm⁻² and with an energy of implantation of between 15 and 100 KeV. Finally, a backside drain contact metal 225 may be formed on the backside of the substrate composition. The backside drain contact metal 225 may be any suitable conductive material for example polycrystalline silicon or a metal such as nickel, copper, iron aluminum, tungsten, silver, gold, or any combination thereof.

While aspects of the present disclosure make reference to drain and source regions, it should be understood that the disclosure is not limited to implementation of FET devices and may also be applied to IGBT type devices. In which case the drain region corresponds to the IGBT collector and the source corresponds to the IGBT emitter. Additionally, it should be understood that the distribution of surface electric field in the device may be adjusted by changing the spacing between termination trench structures and/or transition trench structures.

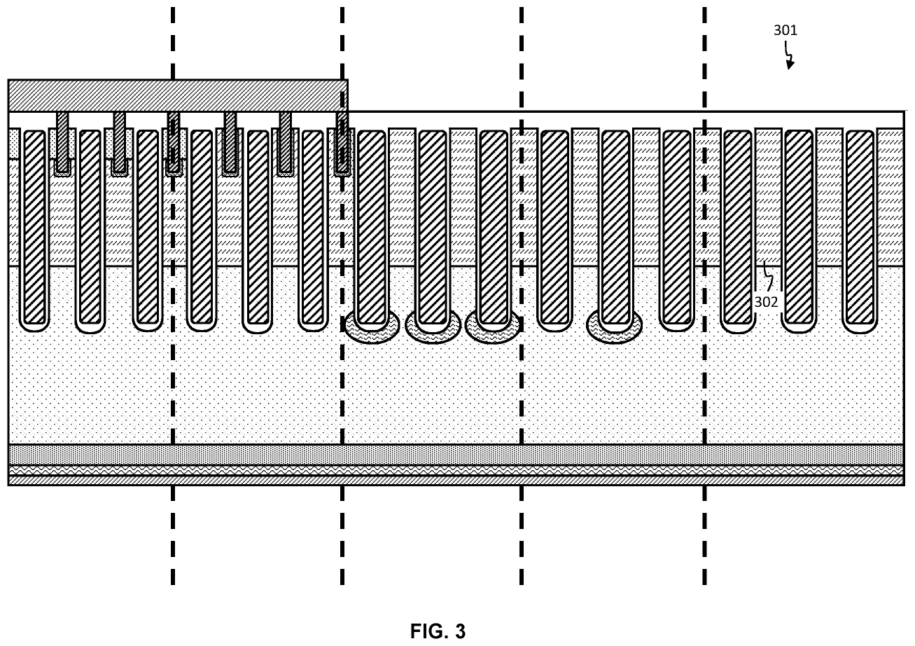

FIG. 3 depicts a side cut away view of an implementation of a semiconductor device having the improved termination regions with a blanket body implant in the third type of termination region according to aspects of the present disclosure. The device shown here is similar to the device shown in FIG. 2. Unlike the previously discussed device the third termination region 301 includes a blanket implanted body region 302 instead of body region pillars. The blanket doped body region in the third termination region 301 may be formed at a similar time as the body region in the active region, transition region, first termination region and second termination region. The body region 302 may be formed with ions of the second conductivity type blanket doped into the substrate layer at a concentration of between 5e¹² and 5e¹³ cm⁻² and with an energy of implantation of between 100 and 900 KeV.

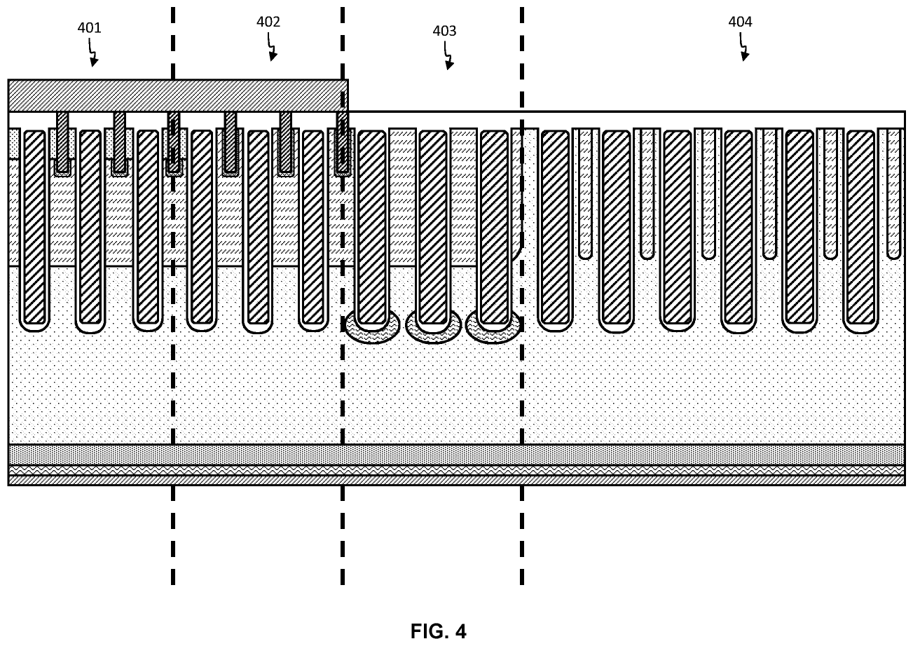

FIG. 4 shows a side cut away view of an implementation of a semiconductor device having improved termination regions of the first and third type according to aspects of the present disclosure. In the implementations shown the semiconductor device includes an active region 401, transition region 402, first termination region 403 and third type termination region 404 and is similar to the device shown in FIG. 2. Unlike the semiconductor device of FIG. 2 the device shown here does not include a second type termination region. The third termination region 404 here is similar in layout to the third termination region shown in FIG. 2 having pillars of body region formed in the mesas between the third termination trench structures and the semiconductor substrate composition does not include BGRs located underneath the third termination trench structures.

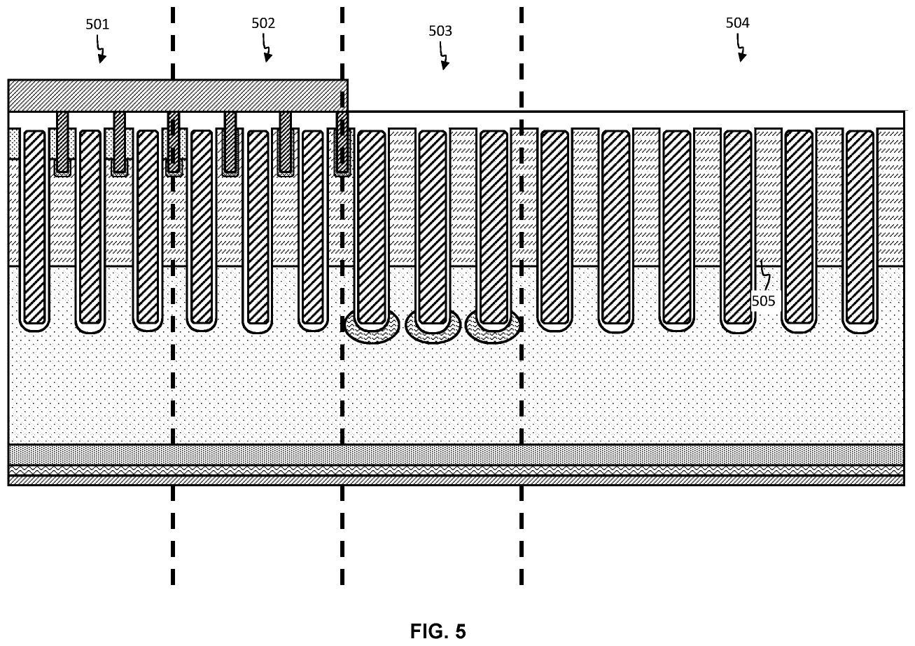

FIG. 5 depicts a side cut away view of an implementation of a semiconductor device having improved termination regions with a first type and third type termination region having a blanket implant body region according to aspects of the present disclosure. The implementations shown is similar to the device shown in FIG. 3 and includes an active region 501, transition region 502, first termination region 503 and a third type termination region 504. Unlike FIG. 3 this implementation does not include a second termination region. Here the third termination region 504 includes a blanket doped body region 505 and the substrate composition does not include BGRs located underneath the third termination trench structures.

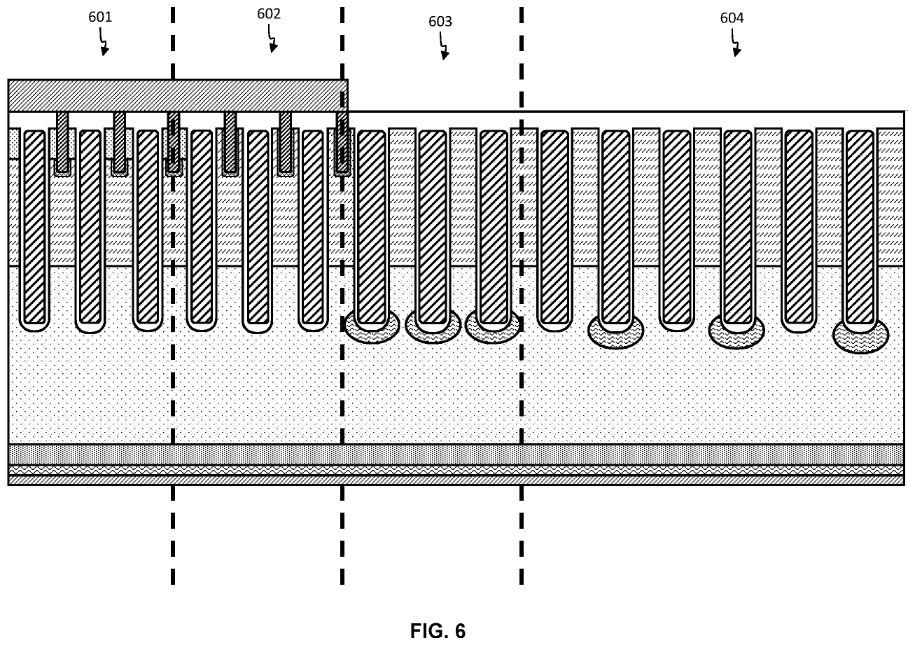

FIG. 6 shows a side cut away view of an implementation of a semiconductor device having improved termination regions with a first type termination region and a second type termination region according to aspects of the present disclosure. As shown the device here includes an active region 601, transition region 602, first termination region 603 and second type termination region 604. Unlike FIG. 3 this implementation does not include a third termination region. The second type termination region 604 has a semiconductor substrate that includes a subset of second termination trench structures with a BGR located near the bottom. In this implementation a BGR is located near the bottom of every other second termination trench.

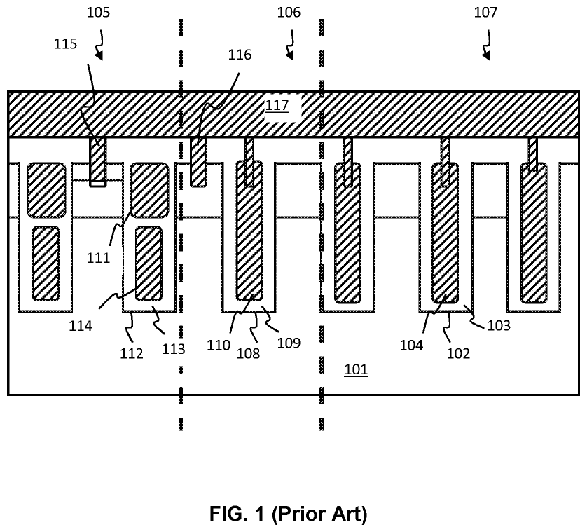

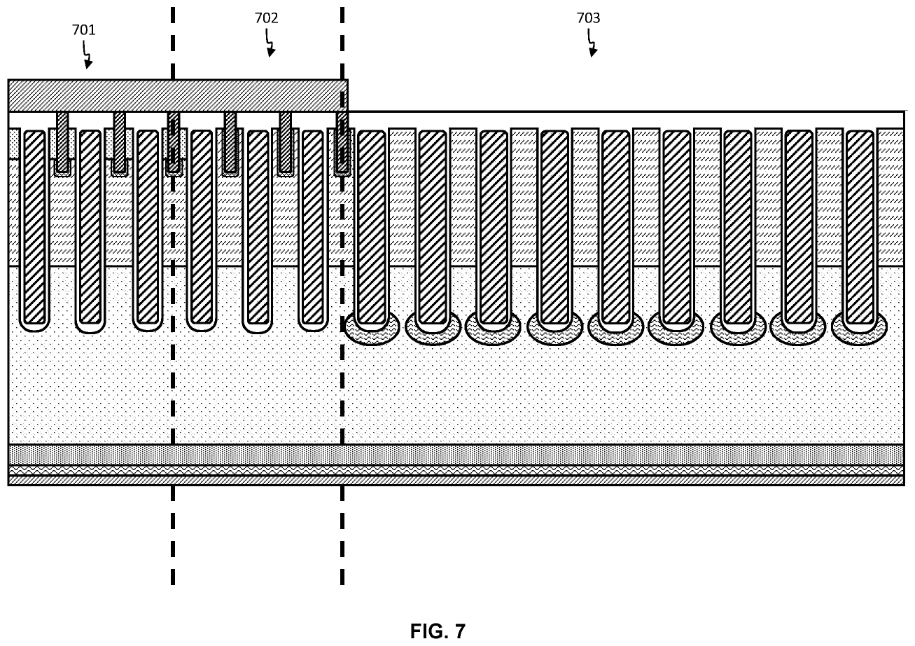

FIG. 7 depicts a side cut away view of an implementation of a semiconductor device having improved termination regions with a first type termination region according to an aspect of the present disclosure. The device here is similar to the device shown in FIG. 1 but does not include a Second type of termination region or a third type of termination region. As shown the improved semiconductor device includes an active region 701, a transition region 702 and a first type termination region 703. The first termination region 703 includes a semiconductor substrate having BGRs located underneath each termination trench and blanket doped body region.

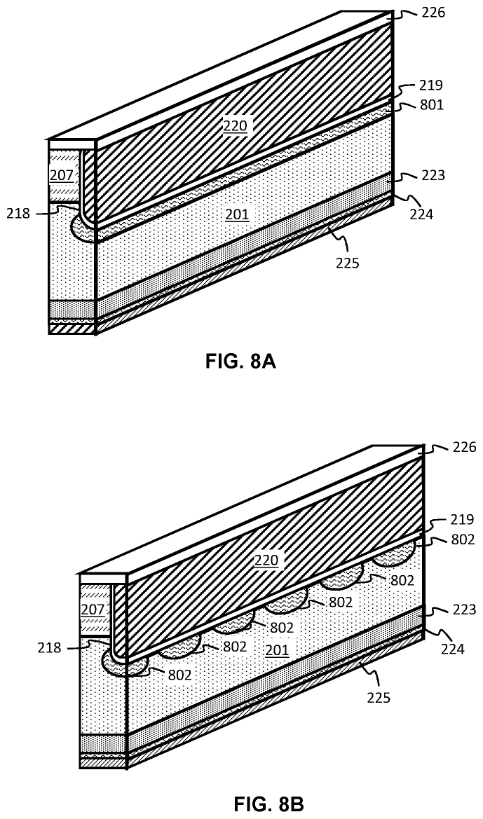

FIG. 8A is a cut away three-dimensional view showing a width of a substrate composition having a axially continuous BGR located along the bottom of a termination trench structure according to aspects of the present disclosure. The cross-section shown in FIG. 8A may be that of any termination region having a BGR, for example a cross-section along line A in FIG. 2. In the implementation shown the BGR 801 is axially continuous along the length of the termination trench. The BGR 801 may be implanted in a continuous region axially near the bottom of the termination trench. The BGR 801 may be formed with ions of the second conductivity type with a concentration of between 1e12 and 5e13 cm⁻² and with an energy of implantation of between 30 and 300 KeV. While aspects of the present disclosure discuss the BGRs in relation to a first type of termination region wherein a BGR is located in an area of the substrate underneath every termination trench aspects of the present disclosure are not so limited. As such the previously discussed continuous BGR may also be implemented in the second type termination region wherein BGRs are located under a subset of second termination trenches for example and without limitation every other second termination trench.

FIG. 8B is a cut away three-dimensional view showing a width of a substrate composition having an intermittent BGR located at the bottom of a termination trench structure according to aspects of the present disclosure. The width of the substrate composition shown may be any termination region having a BGR for example a cross section along line A in FIG. 2. In the implementation shown the BGR 802 is non-continuously distributed axially along the length of the termination trench. The BGR 802 may be implanted with a masked implant in an intermittent region axially near the bottom of the termination trench. The BGR 802 may be formed with ions of the second conductivity type with a concentration of between 1e¹² and 5e13 cm⁻² and with an energy of implantation of between 30 and 300 KeV.

While aspects of the present disclosure discuss the BGRs in relation to a first type of termination region wherein a BGR is located in an area of the substrate underneath every termination trench aspects of the present disclosure are not so limited. As such the previously discussed intermittent BGR may also be implemented in the second type termination region wherein BGRs are located under a subset of second termination trenches for example and without limitation every other second termination trench. An advantage of the intermittent BGR implant is that the average dopant concentration may be finely controlled by increasing or decreasing the number of BGR regions axially dispersed along the width axis of the termination trench. The BGR concentration may be used to control the electric field on the surface of the semiconductor substrate (also referred to herein as the electric field) where too high a BGR pushes the field away from the active region and too low a field pulls the field toward the active region. Limiting the average BGR concentration allows the device to support an optimal electric field distribution and thus a higher breakdown voltage. In some implementations the objective of the device layout may be to shape the electric field to be located in the middle of the termination regions (i.e., the second termination region).

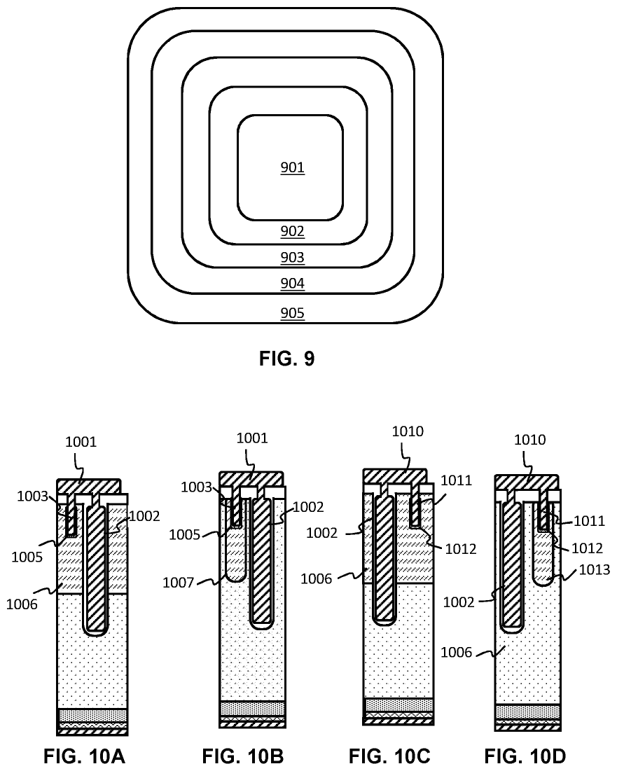

FIG. 9 is a diagram depicting a top-down view of the device including improved termination regions according to aspects of the present disclosure. Here the top-down view is illustrative of the layout of termination regions and active regions according to aspects of the present disclosure. As shown the active region 901 is in a square shaped configuration. The transition region 902 surrounds the active region 901. The first type termination region 903 may be wrapped around transition region 902. A second type termination region 904 may surround the first termination region 903. Alternatively, a third termination region may surround the first termination region (not shown). The third type termination region 905 surrounds the second termination region 904.

The termination trench electrodes shown in FIG. 2 through FIG. 8 are depicted floating and electrically isolated from the substrate composition but aspects of the present disclosure are not so limited. In some implementations the electrodes of the termination structures may be conductively coupled to the substrate through a body connection.

FIG. 10A is a cut away side view of the semiconductor device showing an implementation that includes a body connection to the termination trench electrode on a side near the active region according to an aspect of the present disclosure. In the implementation shown the device area includes a blanket doped body region 1006. The termination trench electrode 1002 is conductively coupled to body contact 1003 on a side near the active region. A body contact lead 1001 may run over top the top portion of the trench insulating layer and make conductive contact to the termination trench electrode and the body contact through conductive vias. Additionally, a termination body contact region 1005 may be formed in the body region 1006 around the body contact 1003. The body contact 1003 may be formed by any suitable material for example and without limitation polycrystalline silicon. Similarly, the body contact lead may be made from any suitable material for example polycrystalline silicon or a metal. The termination body contact region may be doped with ions of the second conductivity type to a concentration of between 5e¹² and 5e¹⁵ cm⁻² and with an energy of implantation of between 20 and 350 KeV. This implementation may be used in the first type of termination region, second type of termination region and third type of termination region when the third type of termination region includes a blanket body implant. Though the trenches shown do not include a BGR it should be understood that the body connection may be used in termination regions that include a BGR.

FIG. 10B is a cut away side view of the semiconductor device showing an implementation that includes a body connection to the termination trench electrode on a side near the active region according to an aspect of the present disclosure. In the implementation shown the device area includes a doped pillar of body region 1007. The termination trench electrode 1002 is conductively coupled to body contact 1003 on a side near the active region. A body contact lead 1001 may run over top the top portion of the trench insulating layer and make conductive contact to the termination trench electrode and the body contact through conductive vias. Additionally, a termination body contact region 1005 may be formed in the pillars of the body region 1006 around the body contact 1003.

FIG. 10C is a cut away side view of the semiconductor device showing an implementation that includes a body connection to the termination trench electrode on a side distal from the active region according to an aspect of the present disclosure. In the implementation shown the device area includes a blanket doped body region 1006. The termination trench electrode 1002 is conductively coupled to body contact 1011 on a side distal from the active region. A body contact lead 1010 may run over top the top portion of the trench insulating layer and make conductive contact to the termination trench electrode and the body contact through conductive vias. Additionally, a termination body contact region 1012 may be formed in the body region 1006 around the body contact 1011. This implementation may be used in the first type of termination region, second type of termination region and third type of termination region when the third type of termination region includes a blanket body implant. Though the trenches shown do not include a BGR it should be understood that the body connection may be used in termination regions that include a BGR.

FIG. 10D is a cut away side view of the semiconductor device showing an implementation that includes a body connection to the termination trench electrode on a side distal from the active region according to an aspect of the present disclosure. In the implementation shown the device area includes a body region pillar 1013. The termination trench electrode 1002 is conductively coupled to body contact 1011 on a side distal from the active region. A body contact lead 1010 may run over top the top portion of the trench insulating layer and make conductive contact to the termination trench electrode and the body contact through conductive vias. Additionally, a termination body contact region 1012 may be formed in the body region 1006 around the body contact 1011.

In some implementations each floating termination trench electrode may be coupled to a separate body contact. Alternatively, one or more termination trench electrodes may be conductively coupled together to a body contact. Floating as used herein means that the element is not connected to the drain, source, collector, emitter, or ground electrodes.

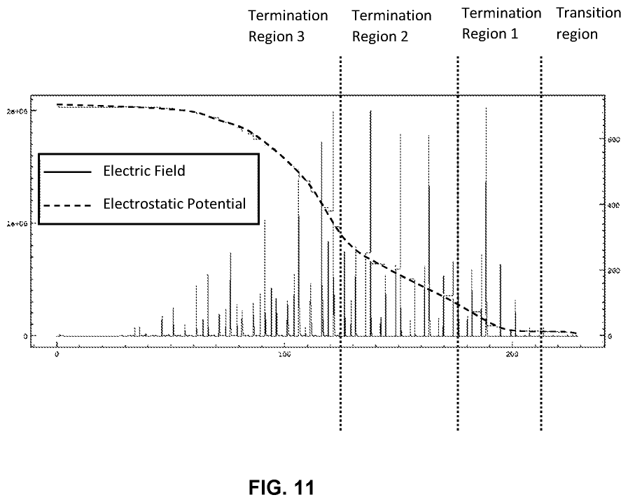

FIG. 11 graphically illustrates a simulated electric field distribution of an implementation of the semiconductor device with improved termination trench structures according to aspects of the present disclosure. The termination trench spacing here is chosen such that the electric field near the surface of the silicon substrate composition (shown in the solid lines) is maximized in the center of the termination regions. Here the center is the second termination region. It can further be seen that the device layout is configured to decrease the electrostatic potential (shown as a dashed line) moving from the third termination region to the transition region. It should be understood that the electric field characteristics of the device may be modified by changing the spacing between termination trench structures and/or the doping concentrations of various regions such as the BGRs.

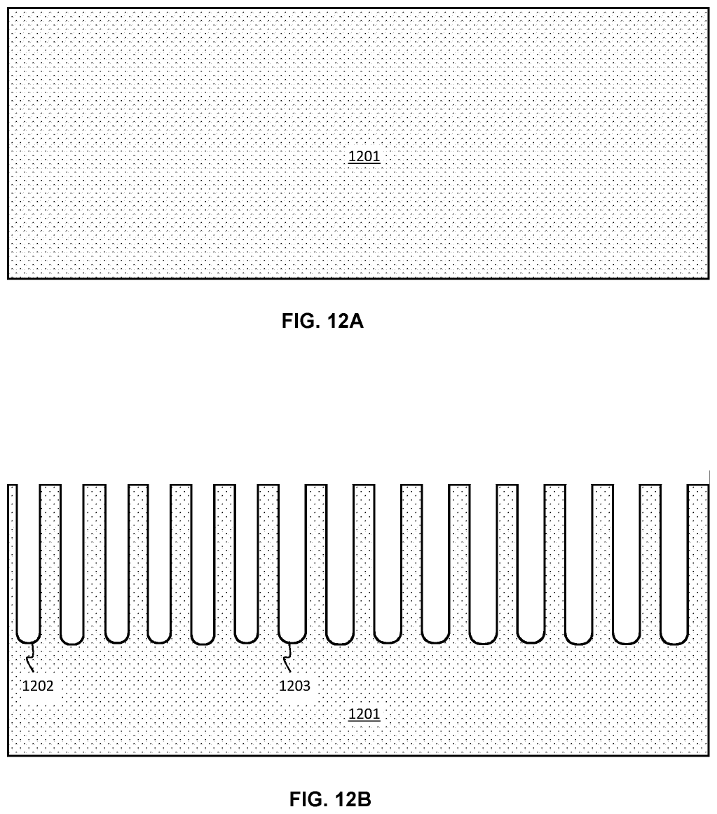

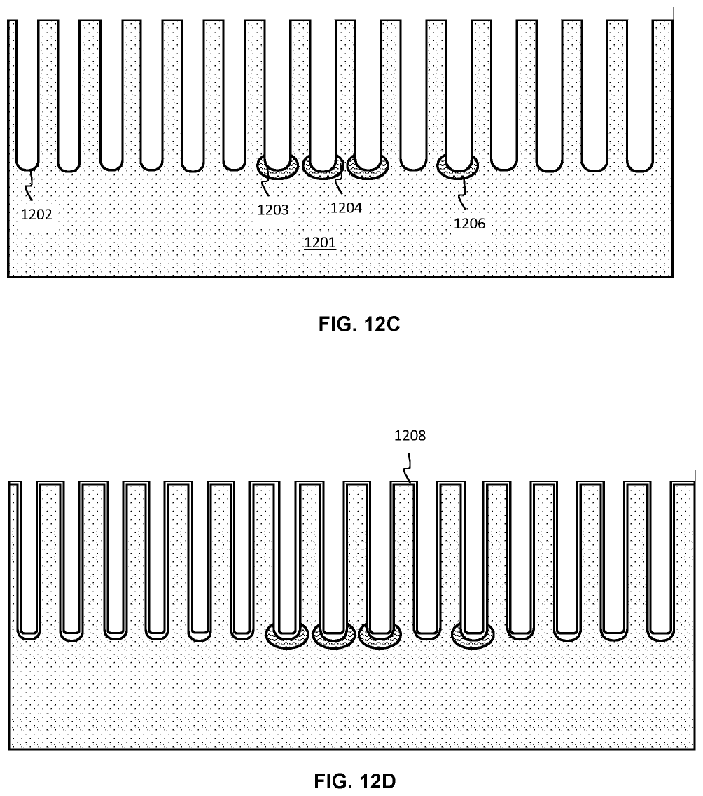

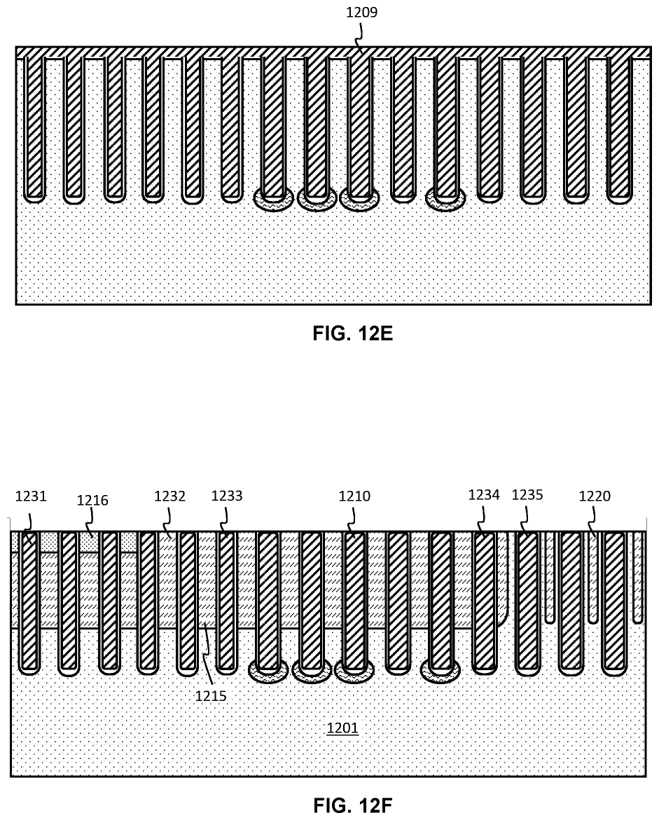

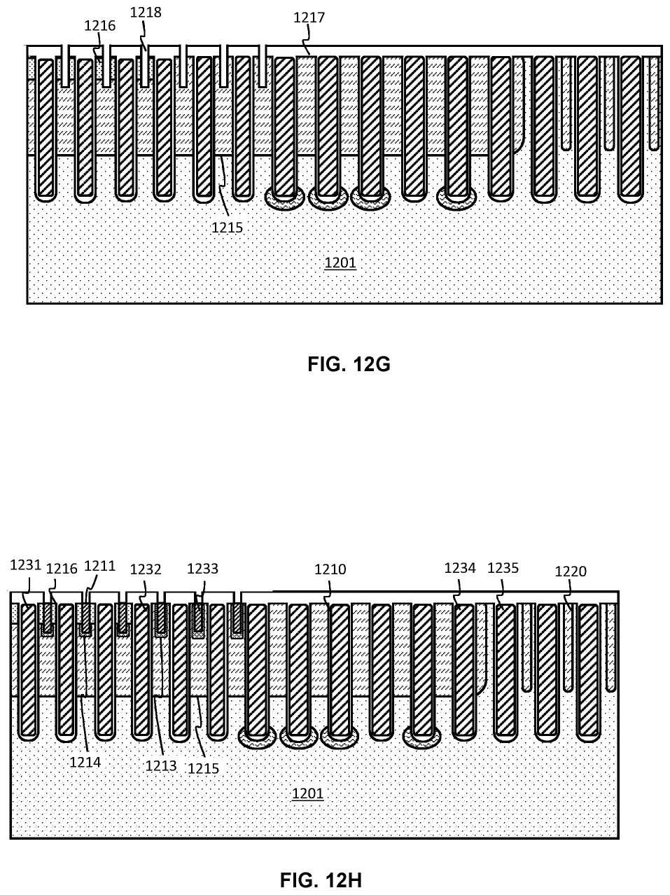

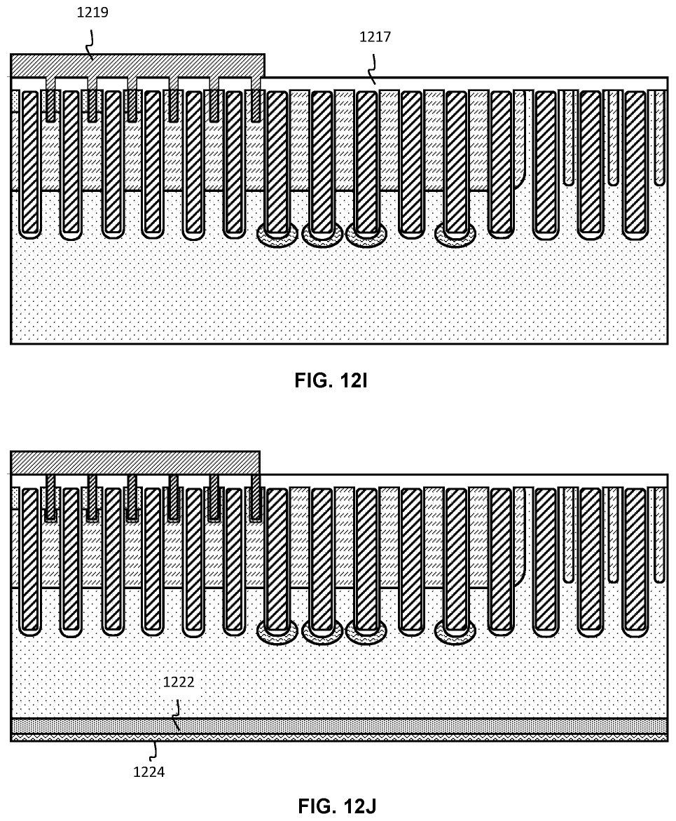

FIGS. 12A-12J are side cross-sectional views showing the formation of the semiconductor device having improved termination regions according to aspects of the present disclosure. FIG. 12A is a cross section view of the initial step of formation of the semiconductor device having improved termination regions. As shown initially a substrate layer 1201 doped with ions of the first conductivity type is provided. The substrate may have an ion concentration of between 1e¹³ and 5e¹⁵ cm⁻³ and may be formed by any suitable formation method for example and without limitation epitaxial growth with Chemical Vapor Deposition (CVD).

Next, as shown in FIG. 12B trenches of various dimensions are formed in the substrate layer 1201. The trenches may be formed by masking followed by etching of the substrate layer and removal of the mask. Any suitable etching method for trench formation may be used for example and without limitation Reactive Ion etching. The mask may be any mask suitable for the etching method for example and without limitation silicon nitride, or silicon oxide hard mask, with patterning. The hard mask may be removed via a suitable mask removal method such as chemical mechanical washing and planarization. As shown, there are two different types of trenches, active and transition region trenches 1202 and termination region trenches 1203. The trenches 1202, 1203 may be formed in a common patterned masking, etching and mask removal process. Alternatively, each trench type may be formed in a separate patterned masking, etching, and mask removal process. Each trench may have a depth from the top surface of the substrate composition between 3 micrometers and 10 micrometers. Trenches of the same type may have the same depth. Patterning of masks herein may be performed via any suitable patterning method for example and without limitation exposure of a photoresist to suitable wavelength light in the desired pattern followed by development with a chemical wash. Patterns may be made from any suitable material for example and without limitation a photosensitive material. As discussed above the voltage characteristics of the device may be modified by changing the spacing of the trenches. For example and without limitation decreasing the trench spacing moves the peak electric field away from the active trenches, and increasing the trench spacing moves the peak electric field towards the active trenches. Proper trench spacings may increase the device's resistance to high voltage as well as improve reliability.

Once the trenches have been formed in the substrate the BGRs and body contact regions may be formed as shown in FIG. 12C. Formation of the BGRs may be performed by masking a surface of the substrate layer with a patterned mask followed by ion implantation with ions of the second conductivity type to an ion concentration of between 1e¹² and 5e¹³ cm⁻² and with an energy of implantation of between 30 and 300 KeV. The BGRs may be formed in a single implant or multiple implantations of varying depths. The masking step may use any suitable masking material that may be patterned. In the termination trenches 1203 for the first termination region, BGRs 1204 may be implanted in area near the bottom of each of the trenches. BGRs 1206 for the second type of termination region may be implanted in a subset of trenches. A subset may be for example every other termination trench, every two termination trenches, every three termination trenches etc. A subset may also include pairs or BGRs formed next to each other every other termination trench, triplets formed next to each other every other termination trench etc. Additionally, aspects of the present disclosure include complex layouts of BGRs such as pairs of BGRs formed every two trench trenches without a BGR underneath and similar.

Next as shown in FIG. 12D an insulating layer 1208 may be formed on the top surface of the semiconductor substrate and in the trenches in a common formation process. This insulating layer may form part of the gate insulating layer, transition trench insulating layer, first termination trench insulating layer, second termination trench insulating layer (if present), and third termination trench insulating layer (if present). Blanket formation of the insulating layer as shown results in the gate insulating layer, transition trench insulating layer, first termination trench insulating layer, second termination trench insulating layer (if present), and third termination trench insulating layer (if present) all having a similar thickness. These insulating layers have equivalent thicknesses. This provides the benefit of a reduced processing costs as for single gate poly IGBT only a single insulating layer formation step is required to form the sidewall insulation of the termination trenches. The thickness of the insulating layer in all regions may be between 0.02 and 0.5 micrometers. The insulating layer 1208 may be made from any suitable insulating material for example and without limitation, silicon dioxide, silicon nitride etc. The insulating layer 1208 may be formed by any suitable method for example and without limitation CVD or thermal oxidation.

A conductive material 1209 is then deposited into the trenches and onto the top surface of the substrate composition as shown in FIG. 12E. The conductive material will eventually form the gate electrodes, active contact plugs, transition contact plugs, first termination electrodes, second termination electrode (if present) and third termination electrodes (if present). The conductive material may be any suitable conductive material for example and without limitation polycrystalline silicon or a metal such as tungsten, titanium, nickel, aluminum, copper, gold, or any alloy thereof. The conductive material 1209 may be deposited on the semiconductor substrate by any suitable deposition method for example and without limitation CVD, sputtering, e-beam evaporation, etc.

After formation of the conductive material for the electrodes the semiconductor substrate composition may undergo planarization and formation of body regions and source regions as shown in FIG. 12F. As shown the substrate composition is planarized to remove the conductive material and insulting material on a top surface and expose the top surface of the substrate composition 1201. Additionally, the planarization exposes the top portion of the active trench electrodes 1231, transition trench electrodes 1233, first termination electrodes 1210, second termination electrodes (if present) 1234, and third termination electrodes (if present) 1235. After planarization, the substrate layer 1201 is blanket doped with ions of the second conductivity type to form the blanket body region 1215. As shown the blanket doped body region extends from active region to the second termination region but aspects of the present disclosure are not so limited, and the third type of termination region may also be blanket doped with ions of the second conductivity type. To form some implementations of the third termination region, areas of the substrate may be masked around the third termination trenches to form pillars of body region 1220 in the mesas of substrate material between the third termination trench structures. The ion concentration of body region may be between 5e¹² and 5e¹⁵ cm⁻² and may be formed with an energy of implantation of between 100 and 900 KeV with one or more implant steps. The body regions 1215 and 1220 may be formed via any suitable implantation method for example and without limitation ion implantation.

Additionally, after formation of the body regions the source regions 1216 may be implanted into an upper portion of the body regions in the active region of the substrate composition. The source regions may be implanted in one or multiple implants via any suitable method for example and without limitation ion implantation. The source regions may be doped with ions of the first conductivity type to a concentration of between 1e¹⁴ and 5e¹⁵ cm⁻² and with an energy of implantation of between 30 and 150 KeV. The substrate composition may be masked to prevent implantation of ions in regions other than the active region.

A top portion of the insulating layer 1217 may be formed on the top surface of the semiconductor substrate composition, as shown in FIG. 12G. The top portion of the insulating layer may be a similar material to the bottom portion of the insulating layers that were shown formed in FIG. 12D. The top portion of the insulating layer may be any suitable insulating material for example and without limitation silicon dioxide or silicon nitride. The insulating layer may be formed by any suitable deposition process, for example and without limitation CVD. Additionally, the insulation material 1217 may be masked and etched to create trenches 1218 through the insulation material 1217 and in the semiconductor substrate composition in the contact region. The trenches 1218 may be etched through the source region 1216 and into the body region 1215 for the active source contacts trenches. For the transition source contact trenches, the trenches 1218 may be etched through the body region 1215. Etching of the active source contact trenches and transition source contact trenches may be performed by any suitable etching process. In some alternative implementations trench formation may be performed without a mask using a self-aligned etching process. An example of a suitable self-aligned process is described in U.S. Pat. No. 9,691,863, which is incorporated herein by reference.

FIG. 12H depicts a step in the formation of the semiconductor region having improved termination regions. After the formation of active source contact trenches and transition source contact trenches, active source contacts 1211 may be formed in the source regions of the active region and transition source contacts 1232 may be formed in the transition region. The contact trenches may be filled with a suitable conductive material, e.g., a metal such as tungsten. In some implementations, the contact trenches may optionally be lined with a diffusion barrier metal, such as titanium and/or titanium nitride before filling the contact trenches with a contact metal, such as tungsten.

As shown, body contact regions may also be implanted at this point before formation of the conductive material in the active source contacts 1211 and transition source contacts 1232. The body contact regions are formed in the substrate composition near the trenches for the source contacts and transition contacts. Two types of body region contacts may be formed, active body contact regions 1214 and transition body contact regions 1213. Here, the transition body contact region 1213 is formed in a region around the transition contact trench starting closer the top surface of the substrate than the active body contact regions 1214 and extend down the depth of the transition contact trench to underneath the body contact trench. The body contact region regions may be formed by creation of a patterned mask on a surface of the substrate composition and implantation of ions into a region of the substrate composition near the bottom of the contact trenches with ions of the second conductivity type. The active body contact regions 1214 and transition body contact regions 1213 may be doped with an energy of implantation of between 20 and 350 KeV and may be doped to a concentration of between 5e¹² and 5e¹⁵ cm⁻². The mask may be any masking material suitable for use with patterning and ion implantation. Once the body contact regions have been created the masks may be removed by any suitable method for example and without limitation chemical mechanical washing and/or planarization.

FIG. 12I shows formation of a source contact layer 1219 over the insulating layer 1217 on the top surface of the substrate composition. The mask over the active contacts and transition contacts may be removed by any suitable mask removal process leaving voids in the insulating material. As shown the source contact layer fills voids in the insulation left by the mask making a conductive connection with the active contact plugs and transition contact plugs. The source contact layer may be any conductive material for example and without limitation polycrystalline silicon, or a metal such as tungsten, titanium, Nickel, aluminum, copper, gold, or any alloy thereof. The source contact layer 1219 may be created by any deposition method for example and without limitation CVD, sputtering, e-beam evaporation etc. While implementations described herein discuss a source region, it should be understood that in an IGBT device the source region is the emitter region.

FIG. 12J shows the device following backside processing of the substrate composition. The implementation shown includes a buffer region 1222 for illustrative purposes but it should be understood that a buffer region is used for punch-through IGBT structures but not used in other types of IGBT structures and MOSFET structures. The buffer region 1222 may be formed by any suitable method for example and without limitation ion implantation or epitaxial growth. The buffer region 1222 may be doped via ion implantation with ions of the first conductivity type to a concentration of between 2e¹² and 3e¹³ cm⁻² and an energy of implantation between 150 and 3 MeV. For epitaxial growth, the buffer region may be grown to a height from the backside surface of the substrate layer of 2-15 micrometers with a resistivity of 0.1 to 2 Ohm-cm.

Next a drain region or a collector region 1224 may be formed in the substrate composition. In FET devices a drain region is formed with ions of the first conductivity type heavily doped into backside of the substrate composition to a concentration of between 1e¹⁴ and 5e¹⁵ cm⁻² and an energy of implantation of between 30 and 150 KeV. The Collector for an IGBT device may be formed with ions of the second conductivity type doped into the substrate composition to a concentration of between 5e¹² and 5e¹⁵ cm⁻² and with an energy of implantation of between 15 and 100 KeV. The collector or drain regions may be formed by any suitable method for example ion implantation.

Finally, a backside drain contact or backside collector contact layer (not shown) may be formed over the corresponding drain or collector. The backside drain contact or backside collector contact layer may be made from any conductive material for example polycrystalline silicon or a metal such as tungsten, titanium, Nickel, aluminum, copper, silver, gold, or a stack with multiple layers of different kinds of conductive material, or an alloy thereof and formed by any suitable deposition method for example and without limitation CVD, sputtering, e-beam evaporation, etc.

Thus, a semiconductor device may be improved termination regions that allow for efficient production in devices that include a single electrode in each of the active trenches. The effect of which is the creation of termination structures that have a trench insulation layer that is similar in thickness to the gate trench insulation layers in the active region while effectively shaping the electrostatic field on the surface of the semiconductor substrate of the device.

While the above is a complete description of the preferred embodiment of the present invention, it is possible to use various alternatives, modifications, and equivalents. Therefore, the scope of the present invention should be determined not with reference to the above description but should, instead, be determined with reference to the appended claims, along with their full scope of equivalents. Any feature described herein, whether preferred or not, may be combined with any other feature described herein, whether preferred or not. In the claims that follow, the indefinite article “A.” or “An” refers to a quantity of one or more of the item following the article, except where expressly stated otherwise. The appended claims are not to be interpreted as including means-plus-function limitations, unless such a limitation is explicitly recited in a given claim using the phrase “means for.”

What is claimed is:

1. A semiconductor device structure comprising:
a semiconductor substrate composition having an active region, a transition region and a first termination region;
an active trench gate structure disposed in the active region;
a first termination trench structure disposed in the first termination region and laterally separated from the active trench by the transition region having a transition trench structure wherein a first termination trench sidewall insulation layer of the first termination trench structure has a similar thickness as a transition trench sidewall insulation layer of the transition trench structure and a gate sidewall insulation layer of the active trench gate structure.

2. The semiconductor device structure of claim 1, further comprising a blanket implanted body region.

3. The semiconductor device structure of claim 1, wherein the first termination region includes two or more first termination trench structures and a first termination region buried guard ring formed near the bottom of the each of the two or more first termination trench structures.

4. The semiconductor device of claim 3 wherein first termination buried guard ring is implanted in regions non-continuously distributed axially near the bottom of every first termination trench.

5. The semiconductor device structure of claim 3, wherein first termination buried guard ring is implanted in a continuous region axially near the bottom of every first termination trench.

6. The semiconductor device structure of claim 1, wherein the semiconductor substrate composition further comprises a second termination region laterally separated from the active region by the transition region and the first termination region; wherein the second termination region includes a second termination trench structure and wherein a second termination trench sidewall insulation layer of the second termination trench structure is the similar thickness as the transition trench sidewall insulation layer and the gate sidewall insulation layer and the first termination trench sidewall insulation layer.

7. The semiconductor device structure of claim 6, wherein the second termination region includes plurality second termination trench structures and a second termination region buried guard ring formed near the bottom of subset second termination trench structures.

8. The semiconductor device of claim 7, wherein the second termination buried guard ring is implanted in regions intermittently distributed axially near the bottom a subset of second termination trenches.

9. The semiconductor device of claim 7, wherein the second termination buried guard ring is implanted in a continuous region axially near the bottom of a subset of second termination trenches.

10. The semiconductor device of claim 6, wherein the semiconductor substrate composition further includes a third termination region laterally separated from the active region by the transition region, the first termination region and the second termination region; wherein the third termination region includes a third termination trench structure, and wherein a third termination trench sidewall insulation layer of the third termination trench structure is the similar thickness as the transition trench sidewall insulation layer and the gate sidewall insulation layer and the first termination trench sidewall insulation layer.

11. The semiconductor device of claim 10, wherein the third termination region further includes two or more third termination trench structures and a third termination body region pillar between each of the two or more third termination trench structures wherein the width of the third termination body region pillar is less than a width of a mesa of semiconductor substrate material between side walls of adjacent third termination trench structures of the two or more third termination trench structures.

12. The semiconductor device of claim 1, wherein the semiconductor substrate composition further includes a third termination region laterally separated from the active region by the transition region, and the first termination region; wherein the third termination region includes a third termination trench structure, and wherein a third termination trench sidewall insulation layer of the third termination trench structure is the similar thickness as the transition trench sidewall insulation layer and the gate sidewall insulation layer and the first termination trench sidewall insulation layer.

13. The semiconductor device of claim 12, wherein the third termination region further includes two or more third termination trench structures and a third termination body region pillar between each of the two or more third termination trench structures wherein the width of the third termination body region pillar is less than a width of a mesa of semiconductor substrate material between side walls of adjacent third termination trench structures of the two or more third termination trench structures.

14. The semiconductor device of claim 1, wherein the semiconductor substrate composition includes a semiconductor substrate doped with ions of the first conductivity, wherein the first conductivity type is opposite a second conductivity type, wherein the active region includes a body region blanket doped with ions of the second conductivity type, a source region doped with ions of the first conductivity type formed in the body region, and body contact region heavily doped with ions of the second conductivity type at the bottom of an active contact trench.

15. The semiconductor device of claim 1, wherein the semiconductor substrate composition includes a semiconductor substrate doped with ions of the first conductivity, wherein the first conductivity type is opposite a second conductivity type, wherein the transition region includes a body region blanket doped with ions of the second conductivity type, and body contact region heavily doped with ions of the second conductivity type at the bottom of a transition contact trench.

16. The semiconductor device of claim 1, wherein the semiconductor substrate composition includes a semiconductor substrate doped with ions of the first conductivity, wherein the first conductivity type is opposite a second conductivity type, wherein the termination region includes a body region blanket doped with ions of the second conductivity type.

17. A method for improved formation of termination trench structure, comprising:
a) forming one or more active region trenches, one or more transition region trenches and one or more first termination region trenches in a semiconductor substrate doped with ions of a first conductivity type wherein the first conductivity type is opposite a second conductivity type;
b) forming an insulating material over the one or more gate trenches, one or more transition region trenches and one or more first termination region trenches to form corresponding one or more gate sidewall insulation layers, one or more transition trench sidewall insulation layers and one or more first termination trench insulation layers during a common formation process.

18. The method of claim 17 further comprising doping a buried guard ring with ions of the second conductivity type into the semiconductor substrate near the bottom of the one or more first termination region trenches before forming the insulating layer.

19. The method of claim 18 further comprising forming two or more second termination trenches and doping a buried guard ring with ions of the second conductivity type into the semiconductor substrate near the bottom of a subset of the two or more second termination trenches.

20. The method of claim 19 wherein b) further comprises forming the insulating material over the two or more second termination trenches to form two or more second termination trench insulation layers.

21. The method of claim 18 wherein a) further comprises formation one or more third termination trenches in the semiconductor substrate wherein none of the third termination region trenches include the buried guard ring.

22. The method of 17 further comprising creation of a body region mask on a surface of the semiconductor substrate in a third termination region and doping body region pillars with ions of the second conductivity through the body region mask in the third termination region and wherein body regions outside the third termination region are blanket implanted with ions of the second conductivity type.

23. The method of claim 22 wherein b) includes forming two or more third termination trenches in the third termination region and wherein a mesa of substrate material formed between adjacent sidewalls of the third termination trenches is wider than a width of the body region pillars.

24. The method of claim 17 further comprising blanket implantation of a body region with ions of the second conductivity type in the semiconductor substrate around the one or more active region trenches, one or more transition region trenches and one or more first termination region trenches.
